(19) United States
(12) Patent Application Publication
(10) Pub. No.: US 2022/0066585 A1
(43) Pub. Date: Mar. 3, 2022

(54) TOUCH DISPLAY PANEL AND ELECTRONIC DEVICE

(71) Applicant: Shenzhen Royole Technologies Co., Ltd., Shenzhen (CN)

(72) Inventors: Jiahao KANG, Shenzhen (CN); Shaowen WANG, Shenzhen (CN); Wenbing HU, Shenzhen (CN); Yumin WANG, Shenzhen (CN); Ze YUAN, Shenzhen (CN); Haojun LUO, Shenzhen (CN)

(21) Appl. No.: 17/412,563

(22) Filed: Aug. 26, 2021

(30) Foreign Application Priority Data
Aug. 26, 2020 (CN) 202010873563.7

(51) Int. Cl. G06F 3/041; G06F 3/044; G09G 3/20

(52) U.S. Cl. CPC G06F 3/0412; G06F 3/04166; G09G 2330/021; G09G 3/20; G06F 3/044

(57) ABSTRACT

The present application relates to a touch display panel and an electronic device. The touch display panel includes: a substrate; and a light-emitting unit layer locating on a side of the substrate comprising a cathode metal layer reused as a touch electrode layer and multiple light-emitting units arranged in an array; the light-emitting units each have a light-emitting cycle comprising a first time period and a second time period staggered from the first time period; the cathode metal layer accesses a touch drive signal when the light-emitting cycle is within the first time period, and the cathode metal layer accesses a display drive signal when the light-emitting cycle is within the second time period. The cathode metal layer according to the present application is reused as the touch electrode layer, and inputs different drive signals in different time periods, which can greatly reduce a thickness of the touch display panel.

### TECHNICAL FIELD

The present application relates to the field of touch display, and in particular, to a touch display panel and an electronic device.

### BACKGROUND

A touch panel and a display panel of an existing touch display panel are stacked at different layers, resulting in a bigger overall thickness, which is not conducive to ultra-thinness and miniaturization of the touch display panel.

### SUMMARY

In view of this, it is necessary to provide a touch display panel, where a cathode metal layer thereof is reused as a touch electrode layer, and inputs different drive signals in different time periods, which can greatly reduce a thickness of the touch display panel.

The present application provides a touch display panel, including:

a substrate; and

a light-emitting unit layer locating on a side of the substrate comprising

a cathode metal layer reused as a touch electrode layer and multiple light-emitting units arranged in an array;

the light-emitting units each having a light-emitting cycle, and the light-emitting cycle comprising a first time period and a second time period staggered from the first time period; wherein

the cathode metal layer accesses a touch drive signal when the light-emitting cycle is within the first time period, and the cathode metal layer accesses a display drive signal when the light-emitting cycle is within the second time period.

Optionally, the cathode metal layer includes multiple cathodes arranged in an array, the touch electrode layer includes multiple touch electrodes arranged in an array, one cathode corresponds to one touch electrode, and the touch display panel further includes:

multiple signal lines, where each of the signal lines is electrically connected to one cathode, and the signal lines are configured as cathode lines of the cathodes and are reused as touch signal lines of the touch electrodes.

Optionally, the touch display panel further includes a data selector, where the data selector is electrically connected to the multiple signal lines, and the data selector is configured to access the touch drive signal in the first time period and is configured to access the display drive signal in the second time period.

Optionally, the light-emitting cycle includes a reset time period, a write time period and a light-emitting time period; and the first time period is within the reset time period, or within the write time period, or spans the reset time period and the write time period.

Optionally, a refresh frequency of the touch drive signal is the same as a refresh frequency of the display drive signal, or the refresh frequency of the touch drive signal is different from the refresh frequency of the display drive signal.

Optionally, the refresh frequency of the touch drive signal is lower than the refresh frequency of the display drive signal when the refresh frequency of the touch drive signal is different from the refresh frequency of the display drive signal.

Optionally, multiple rows of the light-emitting units simultaneously receive the touch drive signal in the first time period of one light-emitting cycle, and multiple rows of the light-emitting units sequentially receive the display drive signal row by row in the second time period of the light-emitting cycle.

Optionally, when the refresh frequency of the touch drive signal is the same as the refresh frequency of the display drive signal, in one light-emitting cycle, a total time length during which cathodes of multiple rows of the light-emitting units simultaneously receive the touch drive signal is less than or equal to a total time length during which the cathodes of the multiple rows of the light-emitting units sequentially receive the display drive signal row by row.

Optionally, each of the cathodes includes multiple sub-cathodes arranged in an array, and the multiple sub-cathodes are electrically connected to each other at the cathode metal layer through leading wires to form one touch electrode, or the multiple sub-cathodes extend mutually to form a whole as one touch electrode.

Optionally, each of the cathodes includes multiple sub-cathodes arranged in an array, and at least one of the sub-cathodes of each of the touch electrodes is electrically connected to all adjacent sub-cathodes; or at least one of the sub-cathodes of each of the touch electrodes is electrically connected to some of the adjacent sub-cathodes.

Optionally, each of the cathodes includes multiple sub-cathodes arranged in an array, and all the sub-cathodes of each of the touch electrodes are electrically connected to each other at a layer at which the signal lines are located.

Optionally, the signal lines and the cathodes are arranged at a same layer, each of the cathodes includes multiple sub-cathodes arranged in an array, and each of the signal lines includes at least two of the sub-cathodes electrically connected to each other.

Optionally, the multiple signal lines are located between the touch electrodes and the substrate.

Optionally, the light-emitting units each further include an anode, and the multiple signal lines and the anode are arranged at a same layer and insulated from each other.

Optionally, the touch display panel further includes a source and a drain, where the source and the drain are located between the substrate and the light-emitting unit layer, respectively, and the multiple signal lines are arranged at a same layer as the source and the drain and insulated from the source and the drain.

Optionally, the touch display panel further includes a gate, where the gate is located between the substrate and the light-emitting unit layer, and the multiple signal lines and the gate are arranged at a same layer and insulated from each other.

Optionally, the touch display panel further includes a light shielding layer, where the light shielding layer is located on a side of the substrate facing the light-emitting unit layer, and the multiple signal lines and the light shielding layer are arranged at a same layer and insulated from each other.

Based on the same conception, the present application further provides an electronic device, including:

a display driving unit, configured to generate the display drive signal; a touch driving unit, configured to generate the touch drive signal; and the above-mentioned touch display panel, where the touch display panel is electrically connected to the display driving unit and the touch driving unit.

Therefore, the cathode metal layer of the touch display panel according to the present application is reused as the touch electrode layer, that is, the cathode metal layer accesses the touch drive signal when the light-emitting cycle is within the first time period, and the cathode metal layer accesses the display drive signal when the light-emitting cycle is within the second time period, which can realize the touch and display functions simultaneously, and also can greatly reduce the thickness of the touch display panel. At the same time, the cathode metal layer is composed of multiple cathodes arranged at intervals, which increases the transparency of the touch display panel and reduces the reflection of ambient light by the touch display panel.

### BRIEF DESCRIPTION OF DRAWINGS

To illustrate structural features and functions of the present application more clearly, the following detailed description will be made with reference to the accompanying drawings and specific embodiments.

FIG. 1 is a schematic structural diagram illustrating a touch display panel according to an embodiment of the present application;

FIG. 2 is a schematic structural diagram illustrating a cathode metal layer according to an embodiment of the present application;

FIG. 3 is a schematic structural diagram illustrating a cathode metal layer according to another embodiment of the present application;

FIG. 4 is a schematic structural diagram illustrating a cathode metal layer according to still another embodiment of the present application;

FIG. 5 is a schematic diagram illustrating the distribution of touch drive signals and display drive signals in each light-emitting cycle according to an embodiment of the present application;

FIG. 6 is a schematic diagram illustrating the distribution of touch drive signals and display drive signals in each light-emitting cycle according to another embodiment of the present application;

FIG. 7 illustrates an operation time sequence of a display drive signal and a touch drive signal according to an embodiment of the present application;

FIG. 8 illustrates an operation time sequence of a display drive signal and a touch drive signal according to another embodiment of the present application;

FIG. 9 illustrates an operation time sequence of a display drive signal and a touch drive signal according to still another embodiment of the present application;

FIG. 10 illustrates an operation time sequence of a display drive signal and a touch drive signal according to still another embodiment of the present application;

FIG. 11 illustrates an operation time sequence of a display drive signal and a touch drive signal according to still another embodiment of the present application;

FIG. 12 is a schematic structural diagram illustrating a drive circuit according to an embodiment of the present application;

FIG. 13 is a schematic structural diagram illustrating cathodes and signal lines according to an embodiment of the present application;

FIG. 14 is a schematic structural diagram illustrating cathodes and signal lines according to an embodiment of the present application;

FIG. 15 is a schematic structural diagram illustrating a touch display panel according to another embodiment of the present application;

FIG. 16 is a schematic structural diagram illustrating a touch display panel according to still another embodiment of the present application;

FIG. 17 is a schematic diagram illustrating a circuit structure of a touch display panel according to still another embodiment of the present application; and

FIG. 18 is a schematic structural diagram illustrating an electronic device according to an embodiment of the present application.

### DESCRIPTION OF EMBODIMENTS

The technical solutions in the embodiments of the present application will be clearly and completely described below in conjunction with the accompanying drawings in the embodiments of the present application. Apparently, the described embodiments are merely some rather than all of the embodiments of the present application. All other embodiments obtained by a person of ordinary skill in the art based on the embodiments of the present application without creative efforts shall fall within the protection scope of the present application.

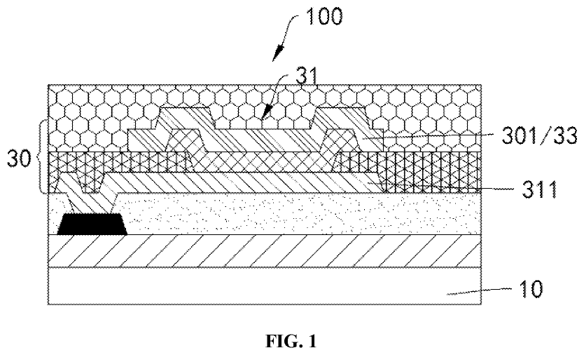

Referring to FIG. 1, a touch display panel 100 according to an embodiment of the present application includes: a substrate 10; and a light-emitting unit layer 30. the light-emitting unit layer 30 includes multiple light-emitting units 31 arranged in an array, the light-emitting units 31 each have a light-emitting emitting cycle, and the light-emitting cycle includes a first time period and a second time period staggered from the first time period; the light-emitting unit layer 30 is located on a side of the substrate 10, the light-emitting unit layer 30 includes a cathode metal layer 33, and the cathode metal layer 33 is reused as a touch electrode layer 33; the cathode metal layer 33 accesses a touch drive signal when the light-emitting cycle is within the first time period, and the cathode metal layer 33 accesses a display drive signal when the light-emitting cycle is within the second time period.

Optionally, the touch display panel 100 according to the present application may be a self-capacitive touch display panel 100.

The cathode metal layer 33 of the touch display panel 100 according to the present application is reused as the touch electrode layer 33. The cathode metal layer 33 accesses the touch drive signal when the light-emitting cycle is within the first time period, and the cathode metal layer 33 accesses the display drive signal when the light-emitting cycle is within the second time period. In this way, touch and display functions can be implemented, and a thickness of the touch display panel 100 can be greatly reduced. In addition, the cathode metal layer 33 includes multiple cathodes arranged at intervals, which increases the transparency of the touch display panel 100 and reduces the reflection of ambient light by the touch display panel 100.

Specifically, the light-emitting units 31 each further include an anode 311, and the anode 311 is located between the substrate 10 and the cathode metal layer 33.

Optionally, the cathode metal layer 33 includes multiple cathodes 331 arranged in an array, the touch electrode layer 33 includes multiple touch electrodes 331 arranged in multiple arrays, and one cathode 331 forms one touch electrode 331.

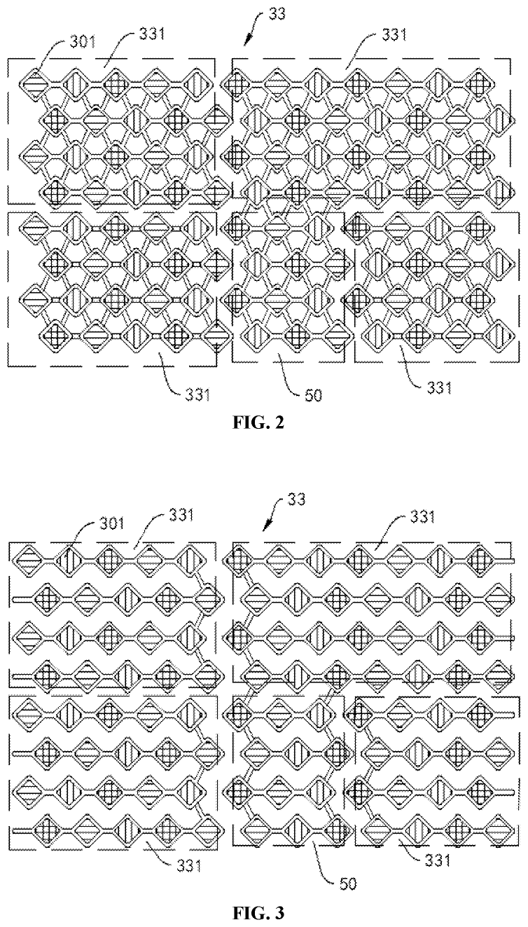

Specifically, referring to FIG. 2 and FIG. 3, in some embodiments, each of the cathodes 331 includes multiple sub-cathodes 301 arranged in an array, and the multiple sub-cathodes 301 are electrically connected to each other at the cathode metal layer 33 through leading wires to form one touch electrode 331.

Different sub-cathodes 301 correspond to different light-emitting units 31. Specifically, in some embodiments, each of the cathodes 331 includes multiple sub-cathodes 301 arranged in an array, and at least one of the sub-cathodes 301 in each of the touch electrodes is electrically connected to all adjacent sub-cathodes; or at least one of the sub-cathodes 301 in each of the touch electrodes is electrically connected to some of the adjacent sub-cathodes 301.

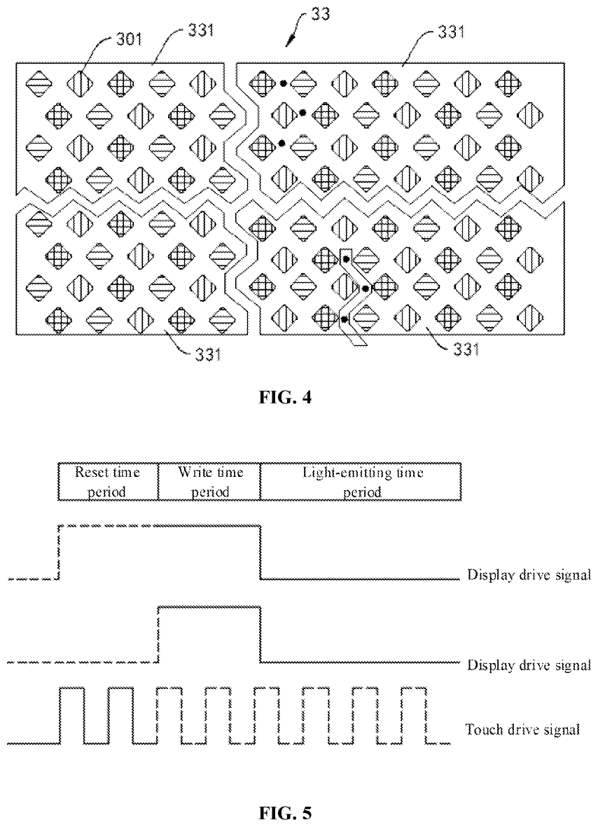

Specifically, referring to FIG. 4, in some other embodiments, the multiple sub-cathodes 301 extend mutually to form a whole as one touch electrode 331.

Specifically, referring to FIG. 5 and FIG. 6, the light-emitting cycle includes a reset time period, a write time period and a light-emitting time period;

and the first time period is within the reset time period, or within the write time period, or spans the reset time period and the write time period. When the light-emitting cycle is within the reset time period and the write time period, the cathode metal layer 33 does not access the display drive signal. During this time period, a pixel circuit is in an off state, a pixel circuit data signal is stored in a storage node (Nst), and an original data signal is returned after the input of the touch drive signal is stopped, i.e., after a touch period ends. Therefore, accessing the touch drive signal in any one of the reset time period and the write time period does not affect a normal display function of the touch display panel 100.

In the embodiment illustrated in FIG. 5, the first time period is within the reset time period. The cathodes 331 of the cathode metal layer 33 access the touch drive signal during the reset time period, and the cathodes 331 accesses the display drive signal during the write time period and the light-emitting time period.

In the embodiment illustrated in FIG. 6, the first time period is within the write time period. The cathodes 331 of the cathode metal layer 33 access the touch drive signal during the write time period, and the cathodes 331 accesses the display drive signal during the reset time period and the light-emitting time period.

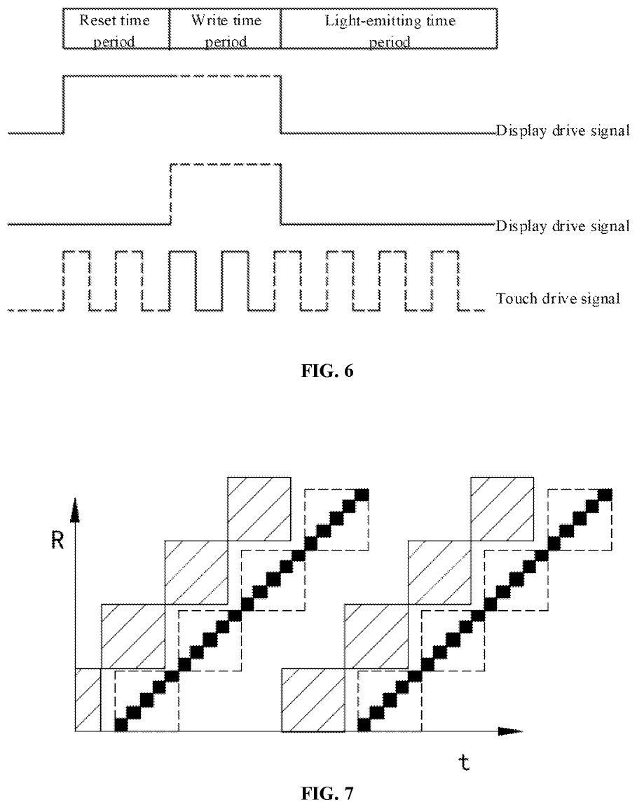

FIG. 7 to FIG. 11 illustrate an operation time sequence of a display drive signal and a touch drive signal according to an embodiment of the present application. In the figures, a horizontal coordinate denotes time (t), a longitudinal coordinate denotes the number of rows (R) of the touch display panel, a black rectangle denotes that during the time corresponding to the range of a horizontal axis, a certain row of a display matrix (corresponding to the coordinate of a longitudinal axis) is refreshed, i.e., display data is sequentially written into display units corresponding to each row of sub-cathodes 301; and a section line rectangle denotes that during the time corresponding to the range of the horizontal axis, a row of touch matrix above several rows of pixels is refreshed (corresponding to the range of the longitudinal axis), i.e., each cathode 331 accesses the touch drive signal as a whole.

Optionally, referring to FIG. 7, in some embodiments, a refresh frequency of the touch drive signal is the same as a refresh frequency of the display drive signal.

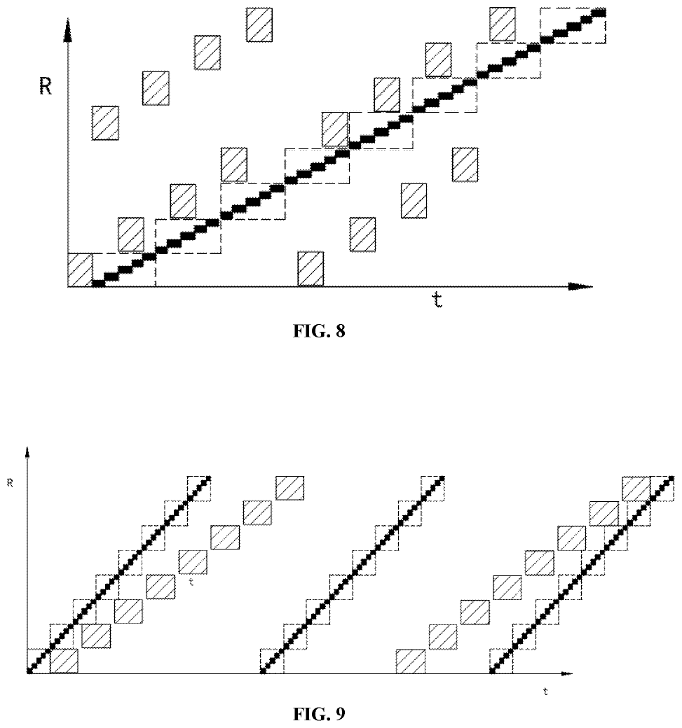

Optionally, referring to FIG. 8 to FIG. 10, in some other embodiments, the refresh frequency of the touch drive signal is different from the refresh frequency of the display drive signal.

Specifically, in the embodiment of FIG. 8, the refresh frequency of the touch drive signal is greater than the refresh frequency of the display drive signal, e.g., the refresh frequency of the touch drive signal is twice as the refresh frequency of the display drive signal.

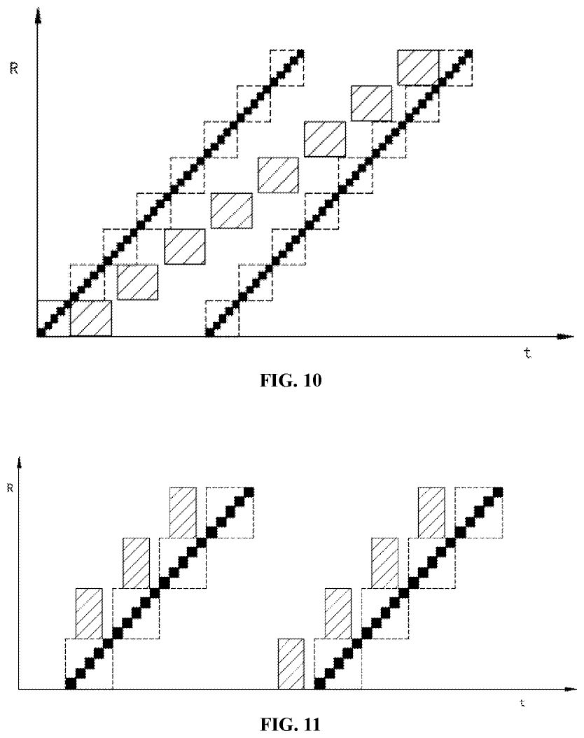

Specifically, in embodiments of FIG. 9 and FIG. 10, the refresh frequency of the touch drive signal is lower than the refresh frequency of the display drive signal, e.g., in the embodiment of FIG. 9, the refresh frequency of the display drive signal is 1.5 times as the refresh frequency of the touch drive signal. In the embodiment of FIG. 10, the refresh frequency of the display drive signal is twice as the refresh frequency of the touch drive signal. In an application scenario that does not require high-resolution induction, reducing the refresh frequency of the touch drive signal is beneficial to reducing power consumption of the touch display panel 100.

Specifically, in some embodiments, multiple rows of light-emitting units 31 simultaneously receive a touch drive signal in a first time period of one light-emitting cycle, and multiple rows of light-emitting units 31 sequentially receive a display drive signal row by row in a second time period of the light-emitting cycle.

Optionally, referring to FIG. 11, in some embodiments, in one light-emitting cycle, a total time length during which cathodes 331 of multiple rows of light-emitting units 31 simultaneously receive a touch drive signal is less than or equal to a total time length during which the cathodes 331 of the multiple rows of light-emitting units 31 sequentially receive a display drive signal row by row.

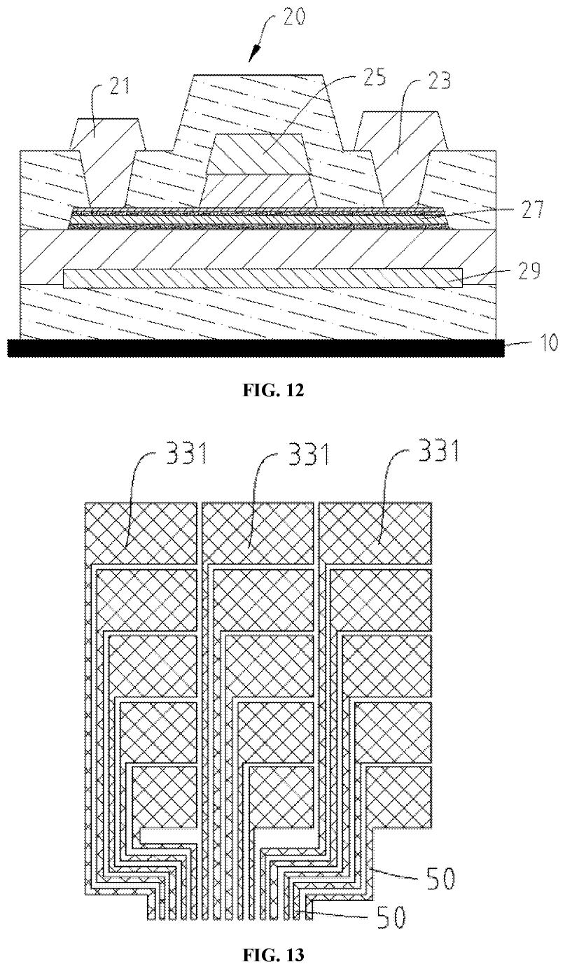

Referring to FIG. 12, specifically, the touch display panel 100 according to the present application further includes a drive circuit 20. the drive circuit 20 is located between the substrate 10 and the light-emitting unit layer 30, electrically connected to each light-emitting unit 31, and configured to drive the light-emitting unit 31 to emit light. The drive circuit 20 includes a source 21, a drain 23, a gate 25 and an active layer 27. The source 21 and the drain 23 are arranged at the same layer at intervals, and are separately connected to the active layer 27. The source 21 or the drain 23 is electrically connected to the anode 311, and the gate 25 is insulated from the active layer 27 at a different layer, and is configured to access a gate signal. Specifically, the drive circuit 20 is a thin-film transistor, and the thin-film transistor may have a top gate structure or a bottom gate structure. When the thin-film transistor is the top gate structure, the drive circuit 20 further includes a light shielding layer 29. The light shielding layer 29 is located between the substrate 10 and the active layer 27, and is configured to prevent light from entering the active layer 27 from one side of the substrate 10 that faces away from the drive circuit 20 and affecting a signal of the drive circuit 20.

Referring to FIG. 13, in some embodiments, the touch display panel 100 according to the present application further includes multiple signal lines 50, each of the signal lines 50 is electrically connected to one cathode 331, and the signal lines 50 are reused as cathode lines of the cathodes 331 and touch signal lines of touch electrodes 331. Specifically, the cathode line is configured to access a low level (Vss), i.e., to access a display drive signal.

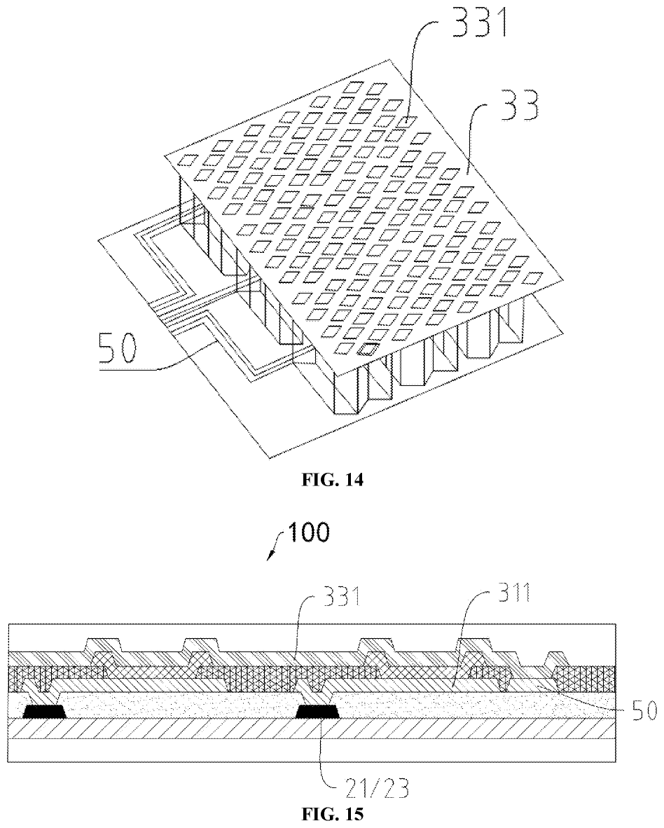

Referring to FIG. 14, in some embodiments, all the sub-cathodes 301 of each of the touch electrodes 331 are electrically connected to each other at a layer at which the signal lines 50 are located. Specifically, all the sub-cathodes 301 first pass through holes to the layer at which the signal lines 50 are located, and then are electrically connected to each other through metal wires of the layer at which the signal lines 50 are located, to form one touch electrode 331. For example, in a specific embodiment, a layer of metal wires is arranged between the substrate 10 and the cathode 331 as signal lines 50, and all the sub-cathodes 301 first pass through holes to the layer at which the metal wires are located, and multiple sub-cathodes 301 are electrically connected to each other by the metal wires to form one cathode 331/touch electrode 331.

Referring to FIG. 2, FIG. 3 and FIG. 13 again, in some embodiments, the signal lines 50 and the cathodes 331 are arranged at a same layer, and each of the signal lines 50 includes at least two sub-cathode 301 electrically connected to each other. That is, the signal line 50 is formed by multiple sub-cathodes 301 electrically connecting to each other.

In some other embodiments, multiple signal lines 50 are located between the touch electrode 331 and the substrate 10.

Referring to FIG. 15, in some embodiments, the multiple signal lines 50 and the anode 311 are arranged at a same layer and insulated from each other.

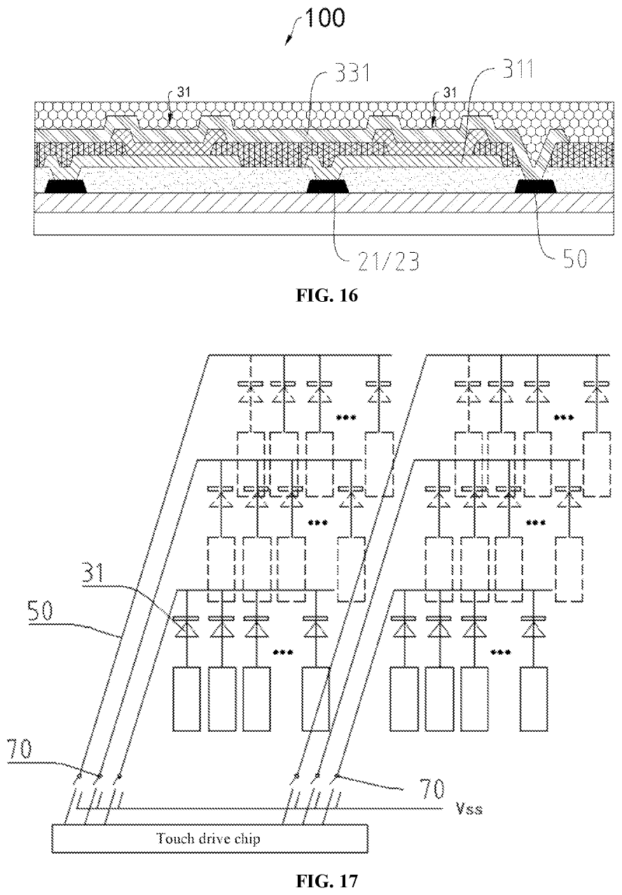

Referring to FIG. 16, in some embodiments, the multiple signal lines 50 are arranged at the same layer as the source 21 and the drain 23 and insulated from the source 21 and the drain 23.

Referring to FIG. 12 again, in some embodiments, the multiple signal lines 50 and the gate 25 are arranged at a same layer and insulated from each other.

Referring to FIG. 12 again, in some embodiments, when the drive circuit 20 is a thin-film transistor with a top gate structure, the multiple signal lines 50 and the light shielding layer 29 are arranged at a same layer and insulated from each other.

It should be understood that the “same layer”, “arrangement at a same layer” and the like in the present application are implemented by making metals or metal alloys in a same process, or by patterning a same metal layer or metal alloy layer. For example, that the signal lines 50 and the anode 311 are arranged at a same layer and insulated from each other means that the signal lines 50 and the anode 311 are prepared in a same process, or the anode 311 and the signal lines 50 are formed by etching (patterning) a same metal layer or metal alloy layer.

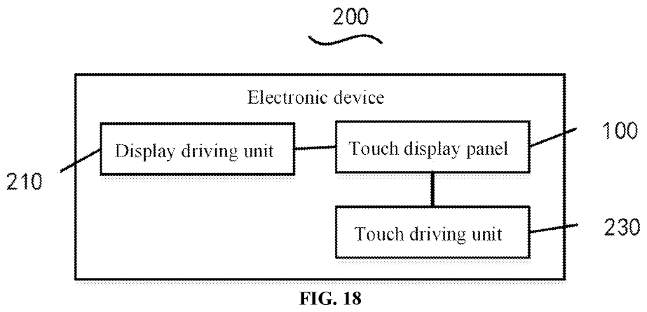

Referring to FIG. 17, in some embodiments, the touch display panel 100 according to the present application further includes a data selector 70. The data selector 70 is electrically connected to the multiple signal lines 50, and the data selector 70 is configured to access the touch drive signal in the first time period and is configured to access the display drive signal in the second time period. Specifically, the data selector 70 electrically connects the signal lines 50 to a touch drive chip and disconnects the signal lines 50 from a display drive chip in a first time period, and electrically connects the signal lines 50 to the display drive chip and disconnects the signal lines 50 from the touch drive chip in a second time period. In the touch display panel 100 according to the present application, the cathodes and the touch electrodes are shared, and the cathode lines and the touch signal lines are reused. Through the data selector 70, the touch drive signal is accessed in the first time period, and the display drive signal is accessed in the second time period, so that light-emitting display and touch driving of the touch display panel 100 can be alternately performed.

Referring to FIG. 18, the present application further provides an electronic device 200, including:

a display driving unit 210, configured to generate the display drive signal;

a touch driving unit 230, configured to generate the touch drive signal; and

the touch display panel 100 according to the embodiment of the present application, the touch display panel 100 is electrically connected to the display driving unit 210 and the touch driving unit 230.

The above are merely specific implementations of the present application, but the protection scope of the present application is not limited thereto. Any person skilled in the art may easily think of various equivalent modifications or replacements within the technical scope disclosed in the present application, and these modifications or replacements should fall within the protection scope of the present application. Therefore, the protection scope of the present application should be subject to the protection scope of the claims.

What is claimed is:

1. A touch display panel, comprising:
a substrate; and
a light-emitting unit layer locating on a side of the substrate comprising a cathode metal layer reused as a touch electrode layer and multiple light-emitting units arranged in an array;
the light-emitting units each having a light-emitting cycle, and the light-emitting cycle comprising a first time period and a second time period staggered from the first time period; wherein
the cathode metal layer accesses a touch drive signal when the light-emitting cycle is within the first time period, and the cathode metal layer accesses a display drive signal when the light-emitting cycle is within the second time period.

2. The touch display panel according to claim 1, wherein the cathode metal layer comprises multiple cathodes arranged in an array, the touch electrode layer comprises multiple touch electrodes arranged in an array, one cathode corresponds to one touch electrode, and the touch display panel further comprises multiple signal lines, each of the signal lines is electrically connected to one cathode, and the signal lines are configured as cathode lines of the cathodes and are reused as touch signal lines of the touch electrodes.

3. The touch display panel according to claim 2, further comprising a data selector electrically connected to the multiple signal lines and configured to access the touch drive signal in the first time period and access the display drive signal in the second time period.

4. The touch display panel according to claim 1, wherein the light-emitting cycle comprises a reset time period, a write time period and a light-emitting time period; and
the first time period is within the reset time period, or within the write time period, or spans the reset time period and the write time period.

5. The touch display panel according to claim 1, wherein a refresh frequency of the touch drive signal is the same as that of the display drive signal, or the refresh frequency of the touch drive signal is different from that of the display drive signal.

6. The touch display panel according to claim 5, wherein the refresh frequency of the touch drive signal is lower than that of the display drive signal when the refresh frequency of the touch drive signal is different from that of the display drive signal.

7. The touch display panel according to claim 5, wherein multiple rows of the light-emitting units simultaneously receive the touch drive signal in the first time period of one light-emitting cycle, and multiple rows of the light-emitting units sequentially receive the display drive signal row by row in the second time period of the light-emitting cycle.

8. The touch display panel according to claim 5, wherein when the refresh frequency of the touch drive signal is the same as that of the display drive signal, in one light-emitting cycle, a total time length during which cathodes of multiple rows of the light-emitting units simultaneously receive the touch drive signal is less than or equal to that during which the cathodes of the multiple rows of the light-emitting units sequentially receive the display drive signal row by row.

9. The touch display panel according to claim 2, wherein each of the cathodes comprises multiple sub-cathodes arranged in an array, and the multiple sub-cathodes are electrically connected to each other at the cathode metal layer through leading wires to form one touch electrode, or the multiple sub-cathodes extend mutually to form a whole as one touch electrode.

10. The touch display panel according to claim 2, wherein each of the cathodes comprises multiple sub-cathodes arranged in an array, and at least one of the sub-cathodes of each of the touch electrodes is electrically connected to all adjacent sub-cathodes; or at least one of the sub-cathodes of each of the touch electrodes is electrically connected to some of the adjacent sub-cathodes.

11. The touch display panel according to claim 2, wherein each of the cathodes comprises multiple sub-cathodes arranged in an array, and all the sub-cathodes of each of the touch electrodes are electrically connected to each other at a layer at which the signal lines are located.

12. The touch display panel according to claim 2, wherein the signal lines and the cathodes are arranged at a same layer, each of the cathodes comprises multiple sub-cathodes arranged in an array, and each of the signal lines comprises at least two of the sub-cathodes electrically connected to each other.

13. The touch display panel according to claim 2, wherein the multiple signal lines are located between the touch electrodes and the substrate.

14. The touch display panel according to claim 2, wherein the light-emitting units each further comprise an anode, and the multiple signal lines and the anode are arranged at a same layer and insulated from each other.

15. The touch display panel according to claim 2, further comprising a source and a drain, wherein the source and the drain are located between the substrate and the light-emitting unit layer respectively, and the multiple signal lines are arranged at a same layer as the source and the drain, and insulated from the source and the drain.

16. The touch display panel according to claim 2, further comprising a gate, wherein the gate is located between the substrate and the light-emitting unit layer, and the multiple signal lines are arranged at a same layer as the gate, and insulated from the gate.

17. The touch display panel according to claim 2, further comprising a light shielding layer, wherein the light shielding layer is located on a side of the substrate facing the light-emitting unit layer, and the multiple signal lines and the light shielding layer are arranged at a same layer and insulated from each other.

18. An electronic device, comprising:
a display driving unit, configured to generate a display drive signal;
a touch driving unit, configured to generate a touch drive signal; and
a touch display panel, wherein the touch display panel is electrically connected to the display driving unit and the touch driving unit; the touch display panel comprises:
a substrate; and
a light-emitting unit layer locating on a side of the substrate comprising a cathode metal layer reused as a touch electrode layer and multiple light-emitting units arranged in an array, wherein the light-emitting unit layer comprises multiple light-emitting units arranged in an array;
the light-emitting units each having a light-emitting cycle, and the light-emitting cycle comprising a first time period and a second time period staggered from the first time period; wherein
the cathode metal layer accesses a touch drive signal when the light-emitting cycle is within the first time period, and the cathode metal layer accesses a display drive signal when the light-emitting cycle is within the second time period.

19. The electronic device according to claim 18, wherein the cathode metal layer comprises multiple cathodes arranged in an array, the touch electrode layer comprises multiple touch electrodes arranged in an array, one cathode corresponds to one touch electrode, and the touch display panel further comprises multiple signal lines, each of the signal lines is electrically connected to one cathode, and the signal lines are configured as cathode lines of the cathodes and are reused as touch signal lines of the touch electrodes.

20. The electronic device according to claim 19, wherein the touch display panel further comprises a data selector electrically connected to the multiple signal lines and configured to access the touch drive signal in the first time period and access the display drive signal in the second time period.
